(19) United States
(12) Patent Application Publication
(10) Pub. No.: US 2007/0064394 A1
(43) Pub. Date: Mar. 22, 2007

(54) Heat dissipating system

(76) Inventors: Chien-Jung Chen, Kaohsiung Hsien (TW); Te-Tsung Chen, Kaohsiung Hsien (TW); Chih-Tsung Hsu, Kaohsiung Hsien (TW)

Correspondence Address: GALLAGHER & LATHROP, A PROFESSIONAL CORPORATION, 601 CALIFORNIA ST, SUITE 1111, SAN FRANCISCO, CA, 94108, US

(21) Appl. No.: 11/392,329

(22) Filed: Mar. 28, 2006

(30) Foreign Application Priority Data
Sep. 21, 2005 (TW) 094216235

(51) Int. Cl. H05K 7/20

(52) U.S. Cl. 361/699

(57) ABSTRACT

A heat dissipating system adapted for cooling an electronic device includes: a heat sink adapted to be connected to the electronic device; a driving mechanism; a cooling mechanism; a coolant circulating conduit adapted for receiving a coolant therein, and connected to the cooling mechanism, the heat sink, and the driving mechanism such that the driving mechanism drives circulation of the coolant in the coolant circulating conduit through the heat sink and the cooling mechanism; and a pressure sensing mechanism including a pressure sensing unit connected to the coolant circulating conduit for measuring the pressure inside the coolant circulating conduit, and an alarm coupled to the pressure sensing unit and activated by the pressure sensing unit when the pressure measured by the pressure sensing unit is below a predetermined value.

### CROSS-REFERENCE TO RELATED APPLICATION

This application claims priority of Taiwanese application no. 094216235, filed on Sep. 21, 2005.

### BACKGROUND OF THE INVENTION

1. Field of the Invention

This invention relates to a heat-dissipating device, more particularly to a heat-dissipating device with a pressure sensing mechanism for detecting leakage of a coolant in a coolant circulating conduit.

2. Description of the Related Art

As technology advances in the field of computers, performance of the computer has become more and more powerful. Therefore, considerable heat is generated by electronic devices, such as a central processing unit (CPU), of the computer, thereby resulting in a high temperature. The high temperature can cause improper shut down of the computer and damage to the data stored in the computer. Thus, heat dissipation is a major concern for computer manufacturers.

FIG. 1 shows a conventional heat dissipating device 1 that includes a heat sink 11, a coolant 12, a driving mechanism 13, a cooling mechanism 14, and a conduit 112 allowing the coolant 12 to flow therein and connected to the heat sink 11 and the driving mechanism 13.

The heat sink 11 includes a body 111 heat-exchangably connected to an electronic device 100, and defines an inner space in the body 111. The coolant 12 is received in the inner space of the heat sink 11, and flows through the inner space of the heat sink 11 so as to carry the heat from the electronic device 100.

The driving mechanism 13 is used to circulate the coolant 12 in the heat dissipating device 1.

The cooling mechanism 14 includes a plurality of heat dissipating fins 142 spaced apart from each other and connected to a tortuous section 141 of the conduit 112.

In operation, the heat generated by the electronic device 100 is transferred to the body 111 of the heat sink 11, and is carried by the coolant 12 to the cooling mechanism 14 so as to be dissipated thereat. The heat dissipating fins 142 of the cooling mechanism 14 contact the tortuous section 141 of the conduit 112 so as to facilitate heat dissipation. With the circulation of the coolant 12, the heat generated by the electronic device 100 is dissipated.

However, because the conventional heat dissipating device 1 is not formed integrally, the coolant is liable to leak in the heat dissipating device 1 as working time increases, thereby resulting in a decrease in the pressure inside the heat dissipating device 1 and a reduction in the heat dissipating efficiency. Therefore, there is a need in the art to provide a heat dissipating system that can detect leakage of the coolant 12.

### SUMMARY OF THE INVENTION

Therefore, the object of the present invention is to rovide a heat dissipating system capable of detecting leakage of a coolant therein.

According to this invention, a heat dissipating system adapted for cooling an electronic device comprises: a heat sink adapted to be connected to the electronic device for absorbing heat from the electronic device; a driving mechanism; a cooling mechanism; a coolant circulating conduit adapted for receiving a coolant therein, and connected to the cooling mechanism, the heat sink, and the driving mechanism such that the driving mechanism drives circulation of the coolant in the coolant circulating conduit through the heat sink and the cooling mechanism so as to transfer heat from the heat sink to the cooling mechanism through the coolant; and a pressure sensing mechanism including a pressure sensing unit connected to the coolant circulating conduit for measuring the pressure inside the coolant circulating conduit, and an alarm coupled to the pressure sensing unit and activated by the pressure sensing unit when the pressure measured by the pressure sensing unit is below a predetermined value.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a schematic view of a conventional heat dissipating device;

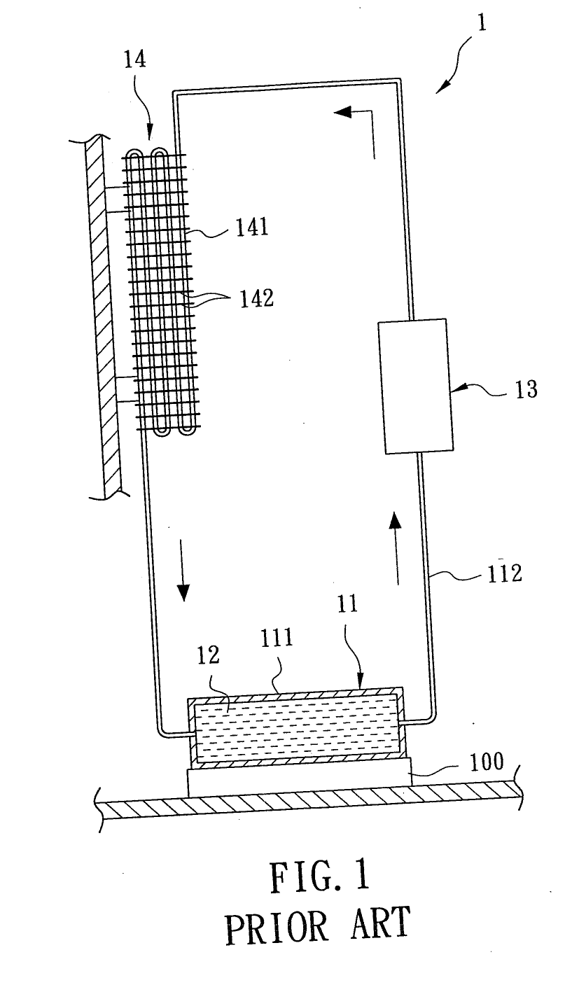

FIG. 2 is a schematic view of the preferred embodiment of a heat dissipating system according to this invention in a normal state; and

FIG. 3 is a schematic view of the preferred embodiment of the heat dissipating system in a state where the pressure inside the heat dissipating system is below a predetermined value.

### DETAILED DESCRIPTION OF THE PREFERRED EMBODIMENT

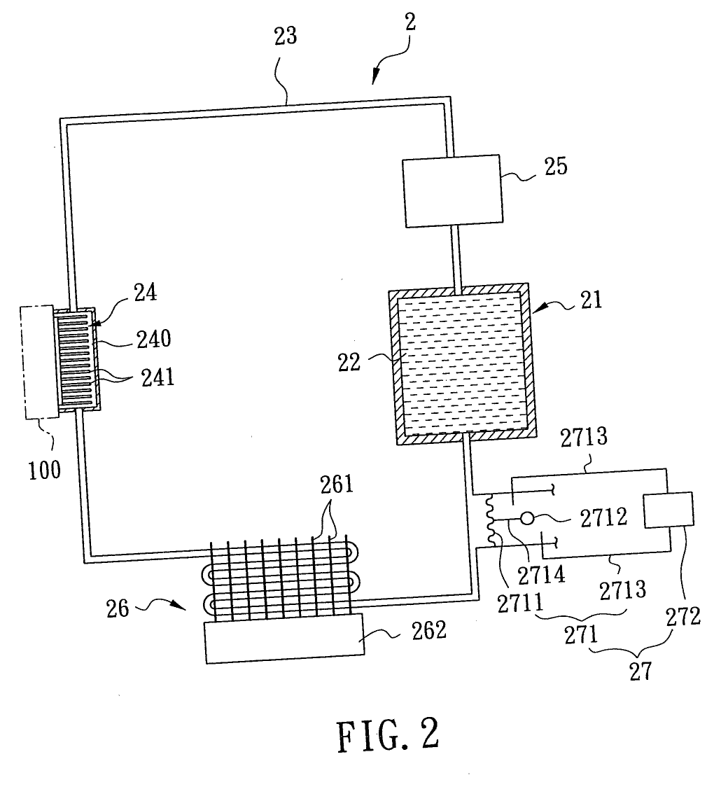

Referring to FIG. 2, the preferred embodiment of a heat dissipating system 2 according to this invention includes: a heat sink 24 adapted to be connected to an electronic device 100 for absorbing heat from the electronic device 100; a driving mechanism 25; a cooling mechanism 26; a coolant circulating conduit 23 adapted for receiving a coolant 22 therein, and connected to the cooling mechanism 26, the heat sink 24, and the driving mechanism 25 such that the driving mechanism 25 drives circulation of the coolant 22 in the coolant circulating conduit 23 through the heat sink 24 and the cooling mechanism 26 so as to transfer heat from the heat sink 24 to the cooling mechanism 26 through the coolant 22; and a pressure sensing mechanism 27. The pressure sensing mechanism 27 includes a pressure sensing unit 271 connected to the coolant circulating conduit 23 for measuring the pressure inside the coolant circulating conduit 23, and an alarm 272 coupled to the pressure sensing unit 271 and activated by the pressure sensing unit 271 when the pressure measured by the pressure sensing unit 271 is below a predetermined value.

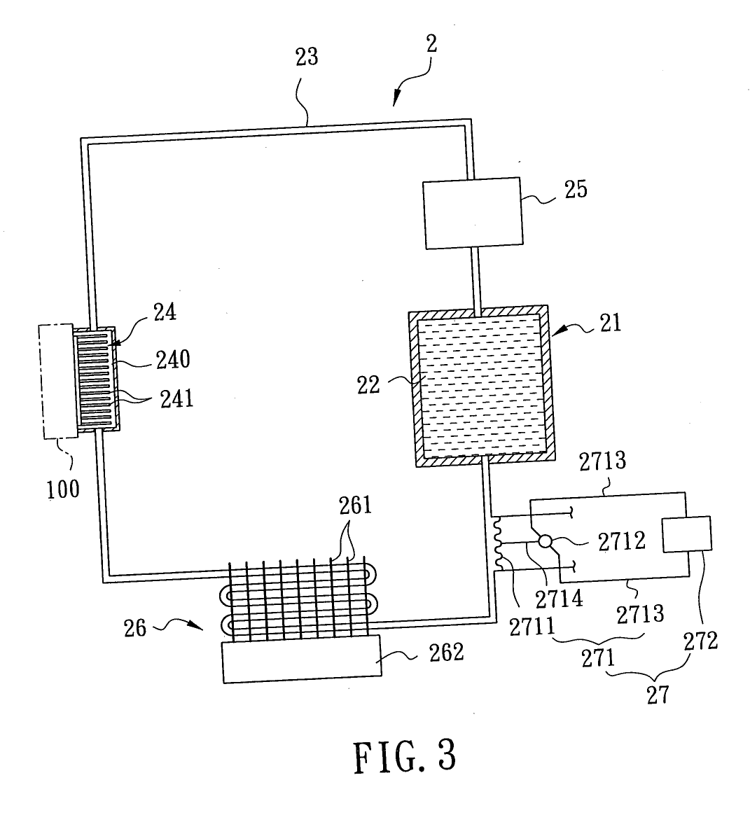

In this embodiment, the pressure sensing unit 271 includes a membrane 2711, a first conducting member 2712, a pair of second conducting members 2713 coupled to the alarm 272, and a connecting member 2714 connecting to the membrane 2711 and the first conducting member 2712 (see FIGS. 2 and 3). As shown in FIG. 2, when the heat dissipating system 2 is at a normal state, the first and second conducting members 2712, 2713 are disconnected, and the alarm 272 is not activated. As shown in FIG. 3, when the pressure inside the coolant circulating conduit 23 is below the predetermined value due to leakage of the coolant 22 in the heat dissipating system 2, the membrane 2711 together with the connecting member 2714 and the first conducting member 2712 moves toward the coolant circulating conduit 23 such that the first conducting member 2712 is electrically connected to the second conducting members 2713, thereby activating of the alarm 272.

In this embodiment, the driving mechanism 25 includes a pump. Preferably, the coolant 22 is water.

In this embodiment, the heat sink 24 includes a container 240 and a plurality of fins 241 disposed in the container 240. The fins 241 are spaced apart from each other, and are in contact with the coolant 22 in the container 240. The fins 241 provide a larger surface area for heat-exchange from the electronic device 100 to the coolant 22, thereby enhancing the heat dissipating efficiency.

In this embodiment, the cooling mechanism 26 includes a plurality of fins 261 and a fan 262. The fins 261 of the cooling mechanism 26 are spaced apart from each other, and contact the coolant circulating conduit 23, such that heat is transferred to the fins 261 of the cooling mechanism 26 from the coolant 22 through the coolant circulating conduit 23. The fan 262 of the cooling mechanism 26 is used to cool the fins 261 of the cooling mechanism 26.

In operation, the heat generated by the electronic device 100 is transferred to the fins 241 of the heat sink 24. The coolant 22 passes through the heat sink 24, and absorbs heat from the fins 241 of the heat sink 24 so as to carry the heat from the heat sink 24. The heated coolant 22 is cooled when passing through the cooling mechanism 26. The cooled coolant 22 is re-circulated to the heat sink 24 through the driving action of the pump 25, thereby continuing the heat-exchanging circulation. When the coolant 22 leaks in the heat dissipating system 2, as described above, the alarm 272 is activated due to movement of the membrane 2711, which indicates that operation of the heat dissipating system 2 is required to be stopped and repair must be conducted.

Preferably, the heat dissipating system 2 further includes a reservoir 21 for receiving the coolant 22. The reservoir 21 is made from a material with low specific heat, and is connected to the coolant circulating conduit 23. The driving mechanism 25 is disposed downstream of the reservoir 21, and draws the coolant 22 from the reservoir 21 into the coolant circulating conduit 23. The pressure sensing mechanism 27 is arranged at a position upstream of the reservoir 21 and downstream of the cooling mechanism 26 so as to measure the pressure of the coolant 22 in the coolant circulating conduit 23 between the reservoir 21 and the cooling mechanism 26.

In this embodiment, the electronic device 100 is directly connected to the heat sink 24. However, this invention should not be limited to the disclosed embodiment. For example, the electronic device 100 can be directly connected to the reservoir 21.

With the inclusion of the pressure sensing mechanism 27 in the heat dissipating system 2 of this invention, leakage of the coolant 22 can be easily detected. The object of this invention is thus met.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A heat dissipating system adapted for cooling an electronic device, said heat dissipating system comprising:
a heat sink adapted to be connected to the electronic device for absorbing heat from the electronic device;
a driving mechanism;
a cooling mechanism;
a coolant circulating conduit adapted for receiving a coolant therein, and connected to said cooling mechanism, said heat sink, and said driving mechanism such that said driving mechanism drives circulation of the coolant in said coolant circulating conduit through said heat sink and said cooling mechanism so as to transfer heat from said heat sink to said cooling mechanism through the coolant; and
a pressure sensing mechanism including a pressure sensing unit connected to said coolant circulating conduit for measuring the pressure inside said coolant circulating conduit, and an alarm coupled to said pressure sensing unit and activated by said pressure sensing unit when the pressure measured by said pressure sensing unit is below a predetermined value.

2. The heat dissipating system of claim 1, wherein said pressure sensing unit includes a membrane that is movable in accordance with the pressure inside said coolant circulating conduit, a first conducting member 2712, a pair of second conducting members 2713 coupled to said alarm 272, and a connecting member 2714 connecting to said membrane 2711 and said first conducting member 2712, said first conducting members being co-movable with said membrane so as to be brought into contact with said second conducting members when the pressure inside said coolant circulating conduit is below the predetermined value so as to activate said alarm.

3. The heat dissipating system of claim 1, wherein said heat sink includes a container and a plurality of fins disposed in said container.

4. The heat dissipating system of claim 1, wherein said cooling mechanism includes a fan and a plurality of fins connected to said coolant circulating conduit.

5. The heat dissipating system of claim 1, wherein said driving mechanism includes a pump.

6. The heat dissipating system of claim 1, further comprising a reservoir connected to said coolant circulating conduit for storing the coolant, said driving mechanism drawing the coolant from said reservoir into said coolant circulating conduit.

7. The heat dissipating system of claim 6, wherein said pressure sensing mechanism is arranged at a position upstream of said reservoir and downstream of said cooling mechanism.
